(19) United States
(12) Patent Application Publication
(10) Pub. No.: US 2023/0246040 A1
(43) Pub. Date: Aug. 3, 2023

(54) VARIABLE ELECTRONIC ELEMENT AND CIRCUIT DEVICE

(71) Applicants: Murata Manufacturing Co., Ltd., Nagaokakyo-shi (JP); JAPAN ADVANCED INSTITUTE OF SCIENCE AND TECHNOLOGY, Nomi-shi (JP)

(72) Inventors: Takaaki MIYASAKO, Nagaokakyo-shi (JP); Eisuke TOKUMITSU, Nomi-shi (JP)

(21) Appl. No.: 18/298,520

(22) Filed: Apr. 11, 2023

Related U.S. Application Data
(63) Continuation of application No. PCT/JP2021/037331, filed on Oct. 8, 2021.

(30) Foreign Application Priority Data
Oct. 12, 2020 (JP) 2020-172070

(51) Int. Cl. H01L 27/13; H01L 21/84; H01L 27/06

(52) U.S. Cl. CPC H01L 27/13; H01L 21/84; H01L 27/0688

(57) ABSTRACT

A variable capacitive element is provided that includes a switch configuring a field effect transistor, and an element that is electrically connected to the switch to configure a capacitor. The element includes a terminal electrode electrically connected to a source electrode, and a terminal electrode that configures a first capacitor with the source electrode and configures a second capacitor at least with the drain electrode.

### CROSS REFERENCE TO RELATED APPLICATIONS

The present application is a continuation of PCT/JP2021/037331, filed Oct. 8, 2021, which claims priority to Japanese Patent Application No. 2020-172070, filed Oct. 12, 2020, the entire contents of each of which are incorporated herein by reference.

### TECHNICAL FIELD

The present invention relates to a variable electronic element that varies a physical quantity of a passive element, and a circuit device including the variable electronic element.

### BACKGROUND ART

In recent years, a variable capacitive element capable of varying capacitance (capacitor) has been developed. Japanese Patent No. 2002-373829 (hereinafter “PTL 1”) discloses a method for varying the capacitance that utilizes a variable capacitive element in which a plate-shaped movable interdigital electrode and a plate-shaped fixed interdigital electrode opposite to the movable interdigital electrode with a minute gap interposed therebetween are provided using a micromachining technique.

In addition, “Evaluation of Channel Modulation in In2O3/(Bi,La)4Ti3O12 Ferroelectric-Gate Thin Film Transistors by Capacitance-Voltage Measurements” to Tokumitsu Eisuke, et al. (Ferroelectrics, 429, p. 15-21, June 2012) (hereinafter “NPL 1”) discloses a method for varying the capacitance that utilizes a variable capacitive element having a two-terminal structure using an on and off operation of a field effect transistor (FET). In the variable capacitive element, when a voltage is applied to the gate electrode in an on state, electrons in a channel region are accumulated at an interface by + polarization of a gate insulating film (e.g., a dielectric) and function as an electrode, so that an electrode area on a source electrode side expands to the same area as the gate electrode. Accordingly, capacitance generated between the source electrode and the gate electrode increases.

However, in the variable capacitive element disclosed in PTL 1, the variable capacitance has a width as small as about several times the variable capacitance before the variable, and the variable capacitance has an insufficient width for use in applications such as a wide-band communication system and a power supply circuit that are required to significantly modulate a frequency.

In addition, in the variable capacitive element disclosed in NPL 1, when a film thickness of the gate insulating film (e.g., the dielectric) is increased in order to increase a withstand voltage, a capacitance value decreases in inverse proportion to the film thickness. Furthermore, in the variable capacitive element disclosed in NPL 1, when the film thickness of the gate insulating film (e.g., the dielectric) is increased, a control voltage applied to the gate electrode increases in proportion to the film thickness, so that power consumption increases.

### SUMMARY OF THE INVENTION

Therefore, it is an object of the present invention to provide a variable electronic element and a circuit device configured to widen a range in which the physical quantity (for example, variable capacitance) of the passive element can be varied and to obtain a sufficient withstand voltage without reducing the physical quantity of the passive element.

Thus, in an exemplary aspect, a variable electronic element is provided that include: a switch that configures a field effect transistor; and an element that is electrically connected to the switch to configure a passive element. Moreover, the switch includes: a source electrode; a drain electrode; a channel formation film that overlaps at least a part of the source electrode and a part of the drain electrode. The variable electronic element includes a gate insulating film that overlaps the channel formation film; and a gate electrode that overlaps the gate insulating film. Moreover, the element includes: a first terminal electrode electrically connected to the source electrode; and a second terminal electrode that configures a first passive element with the source electrode and configures a second passive element at least with the drain electrode.

In another exemplary aspect, a circuit device is provided that includes: a circuit wiring; and the variable electronic element electrically connected to the circuit wiring.

According to the exemplary aspects of the present disclosure, the first passive element is configured between the source electrode and the second terminal electrode, and the second passive element is configured between the drain electrode and the second terminal electrode, so that a range in which the physical quantity of the passive element can be varied can be widened and a sufficient withstand voltage can be obtained without reducing the physical quantity of the passive element.

### BRIEF DESCRIPTION OF DRAWINGS

FIG. 1 is a sectional view illustrating a configuration of a variable capacitive element according to a first exemplary embodiment.

FIG. 2 is a plan view illustrating the configuration of the variable capacitive element of the first exemplary embodiment.

FIG. 3 is a circuit diagram illustrating the variable capacitive element of the first exemplary embodiment.

FIG. 4 is a graph illustrating a width of a variable capacitance of the variable capacitive element according to the first exemplary embodiment.

FIGS. 5(a) to 5(f) are sectional views illustrating a method for manufacturing the variable capacitive element of the first exemplary embodiment.

FIG. 6 is a circuit diagram illustrating a multi-valued variable capacitive element of the first exemplary embodiment.

FIGS. 7(a) and 7(b) are sectional views illustrating a configuration of a variable capacitive element according to a modification of the first exemplary embodiment.

FIG. 8 is a sectional view illustrating a configuration of a variable inductance element according to a second exemplary embodiment.

FIG. 9 is a circuit diagram illustrating the variable inductance element of the second exemplary embodiment.

FIGS. 10(a) and 10(b) are circuit diagrams illustrating a circuit device according to a third exemplary embodiment.

FIGS. 11(a) and 11(b) are graphs illustrating a frequency characteristic of the circuit device of the third exemplary embodiment.

FIG. 12 is a block diagram illustrating a circuit device according to a fourth exemplary embodiment.

FIGS. 13(a) and 13(b) are timing charts illustrating switching timing of the circuit device of the fourth exemplary embodiment.

FIG. 14 is a block diagram illustrating a circuit device according to a fifth exemplary embodiment.

FIG. 15 is a circuit diagram of a circuit device according to a sixth exemplary embodiment.

FIG. 16 is a graph illustrating a switching characteristic of the circuit device of the sixth exemplary embodiment.

FIG. 17 is a sectional view illustrating a configuration of a variable capacitive element according to a seventh exemplary embodiment.

FIG. 18 is a plan view illustrating the configuration of the variable capacitive element of the seventh exemplary embodiment.

FIG. 19 is a sectional view illustrating a configuration of a variable capacitive element according to an eighth exemplary embodiment.

FIG. 20 is a plan view illustrating the configuration of the variable capacitive element of the eighth exemplary embodiment.

FIG. 21 is a sectional view illustrating a configuration of a variable capacitive element according to a modification of the eighth exemplary embodiment.

FIG. 22 is a sectional view illustrating a configuration of a variable capacitive element according to a modification.

FIG. 23 is a view illustrating a relationship between capacitance and a holding voltage of the variable capacitive element.

FIG. 24 is a diagram for explaining the relationship between the capacitance and the retention time of the variable capacitive element.

### DETAILED DESCRIPTION OF EMBODIMENTS

With reference to the drawings, a variable electronic element according to an exemplary embodiment will be described in detail below. A variable electronic element is an element configured to vary a physical quantity of an included passive element, which includes a capacitor, an inductor, a resistor, and the like. In the drawings, the same reference numeral denotes the same or corresponding parts.

### First Exemplary Embodiment

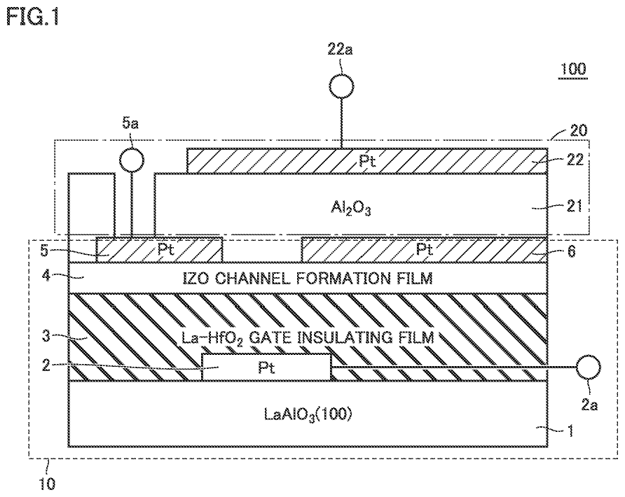

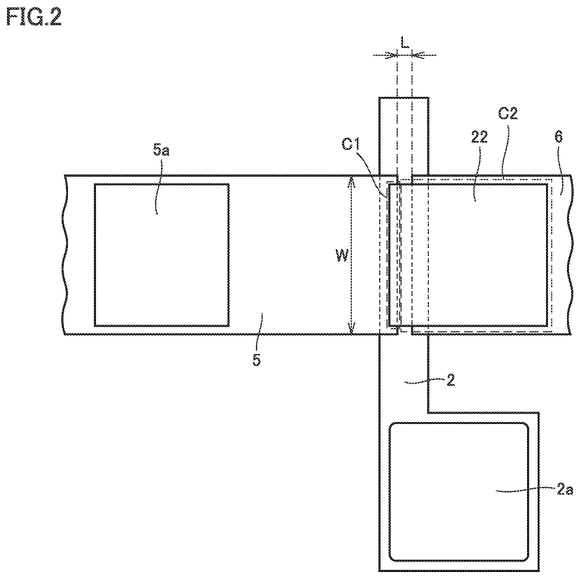

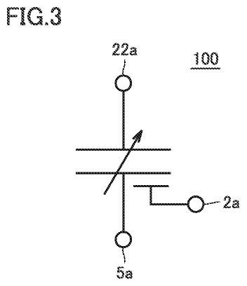

In a first embodiment, a variable capacitive element in which the included passive element is the capacitor and capacitance can be varied will be described with reference to the drawings. FIG. 1 is a sectional view illustrating a configuration of a variable capacitive element 100 according to a first exemplary embodiment. FIG. 2 is a plan view illustrating the configuration of variable capacitive element 100 of the first embodiment. FIG. 3 is a circuit diagram illustrating variable capacitive element 100 of the first embodiment.

As shown, variable capacitive element 100 in FIG. 1 includes a switch portion 10 (also referred to as a “switch”) configuring a field effect transistor formed on a semiconductor substrate 1 and an element portion 20 (also referred to as a “element”) that is electrically connected to switch portion 10 and configures a passive element. Element portion 20 is provided above switch portion 10, for example, on top of switch portion 10.

As further shown, switch portion 10 includes a gate electrode 2, a gate insulating film 3, a channel formation film 4, a source electrode 5, and a drain electrode 6. In switch portion 10 of FIG. 1, gate electrode 2 is formed on semiconductor substrate 1, gate insulating film 3 and channel formation film 4 are sequentially formed so as to overlap gate electrode 2, and source electrode 5 and drain electrode 6 are respectively formed on gate insulating film 3 and channel formation film 4. In general, the term “overlap” means overlapping in the thickness (e.g., vertical) direction or planar view of the variable capacitive element 100 as shown in the exemplary aspect.

According to the exemplary aspect, switch portion 10 is an oxide field effect transistor (FET). For semiconductor substrate 1, for example, lanthanum aluminate (LAO) is used, and gate electrode 2 is formed of platinum (Pt) on the lanthanum aluminate in a predetermined pattern of FIG. 2. For example, a La—HfO₂ film having a film thickness of 70 nm is used for gate insulating film 3, and an IZO film having a film thickness of 25 nm is used for channel formation film 4. Source electrode 5 and drain electrode 6 are formed of platinum (Pt) in the predetermined pattern of FIG. 2 on channel formation film 4 of the IZO film. Although a terminal electrode 5a (e.g., a first terminal electrode) is provided on source electrode 5 in FIG. 2, source electrode 5 itself may be used as terminal electrode 5a in an exemplary aspect. In switch portion 10, for example, a channel width W is set to 100 μm, and a channel length L is set to 10 μm.

Element portion 20 is provided above switch portion 10 and includes an Al₂O₃ film of a dielectric 21 and a terminal electrode 22 (e.g., a second terminal electrode) of platinum (Pt) formed to overlap dielectric 21. Terminal electrode 22 is formed in the predetermined pattern of FIG. 2. As illustrated in FIG. 2, gate electrode 2 is extended from a region where source electrode 5 and drain electrode 6 overlap each other, and a control electrode terminal 2a is provided on gate electrode 2.

Element portion 20 configures a first capacitor (e.g., a first passive element) between source electrode 5 and terminal electrode 22, and configures a second capacitor (e.g., a second passive element) at least between drain electrode 6 and terminal electrode 22. As illustrated in FIG. 2, the first capacitor is a portion C1 where source electrode 5 and terminal electrode 22 overlap each other in planar view. The second capacitor is a portion C2 where drain electrode 6 including channel formation film 4 and terminal electrode 22 overlap each other in planar view.

In variable capacitive element 100, when switch portion 10 is in an off state, a gate voltage greater than or equal to a threshold is not applied to gate electrode 2, so that an electron depletion layer exists at a position of channel formation film 4 overlapping gate electrode 2 in planar view and source electrode 5 and drain electrode 6 are not electrically connected. For this reason, because a voltage is applied only between source electrode 5 and the portion of terminal electrode 22 opposite to source electrode 5, variable capacitive element 100 has the capacitance of only the first capacitor.

However, in the variable capacitive element 100, when switch portion 10 is in an on state, the channel is formed by applying the gate voltage greater than or equal to the threshold to gate electrode 2, and source electrode 5 and drain electrode 6 are electrically connected. For this reason, the voltage is applied between source electrode 5 and drain electrode 6 (including channel formation film 4 therebetween) and opposing terminal electrode 22, so that variable capacitive element 100 becomes a combined capacitance of the first capacitor and the second capacitor.

That is, in variable capacitive element 100, switch portion 10 is turned on and off to switch between a configuration where the first capacitor element is turned on in element portion 20 and a configuration where the first capacitor and a second capacitor element are turned on in element portion 20, thereby varying the capacitance of the capacitor. Variable capacitive element 100 is a variable capacitive element that is divided into switch portion 10 that operates on and off by the voltage applied to gate electrode 2 (e.g., a control electrode terminal 2a), terminal electrode 5a (e.g., a first terminal electrode), and element portion 20 that operates on terminal electrode 22 (e.g., a second terminal electrode), and operates on three terminals. For this reason, the structure and configuration of variable capacitive element 100 is different from that of the variable capacitive element disclosed in NPL 1 in which the capacitance is varied by two terminals of the gate electrode and the source electrode.

In switch portion 10, the film thickness of gate insulating film 3 is desirably reduced from the viewpoint of power consumption, and a withstand voltage decreases by reducing the film thickness, but a driving voltage decreases, so that low-voltage driving can be performed. Accordingly, in variable capacitive element 100, by utilizing the structure in which gate electrode 2 of switch portion 10 and element portion 20 are electrically separated, apart from reducing the film thickness of gate insulating film 3 to achieve the low-voltage driving and the low-withstand voltage, the capacitance can be increased by increasing the thickness of dielectric 21 thick and/or configuring dielectric 21 to have a multilayer structure, such that both the high-withstand voltage and high capacitance can be achieved.

In variable capacitive element 100, because gate electrode 2 (e.g., control electrode terminal 2a) of switch portion 10 is electrically separated from terminal electrode 5a (e.g., first terminal electrode) and terminal electrode 22 (e.g., second terminal electrode) of element portion 20, the operation of switch portion 10 is not affected by the signal on the side on element portion 20. As can be seen from the circuit diagram in FIG. 3, terminal electrode 5a (e.g., first terminal electrode) of variable capacitive element 100 and a terminal 22a of terminal electrode 22 (e.g., second terminal electrode) are connected to a converter circuit or the like, while control electrode terminal 2a varying the capacitance is connected to a circuit different from the converter circuit. For this reason, there is a low possibility that the signal applied to control electrode terminal 2a is affected by the signal of the converter circuit.

Furthermore, in variable capacitive element 100, the electric resistance of channel formation film 4 between source electrode 5 and drain electrode 6 can be reduced by shortening channel length L of switch portion 10. Consequently, in variable capacitive element 100, the switching speed (e.g., time constant) of switch portion 10 can be improved in order to vary the capacitance at a high speed.

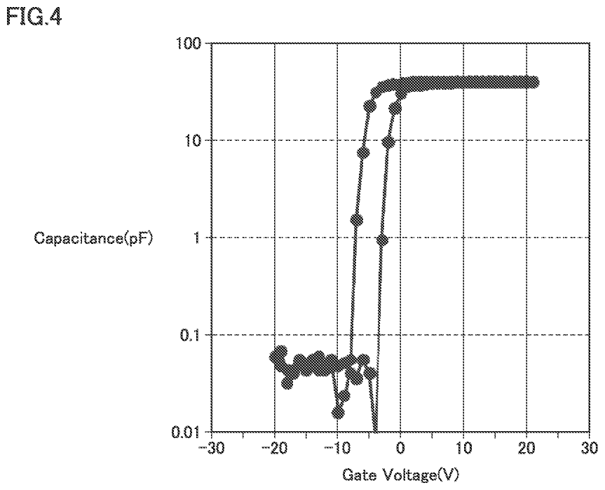

Moreover, the width of the capacitance that can be varied by variable capacitive element 100 will be described below. FIG. 4 is a graph illustrating a width of a variable capacitance of variable capacitive element 100 according to the first embodiment. The width of the capacitance that can be varied by variable capacitive element 100 depends on the capacitance of the second capacitor as described above. That is, the wider the portion C2 where drain electrode 6 and terminal electrode 22 overlap each other in planar view, the larger the capacitance of the second capacitor, and the wider the capacitance that can be varied by variable capacitive element 100.

The graph illustrated in FIG. 4 is an actual measurement value of variable capacitive element 100 in which an area of the portion C2 where drain electrode 6 and terminal electrode 22 overlap each other in planar view is 1000 times (i.e., area ratio 1000 times) an area of the portion C1 where source electrode 5 and terminal electrode 22 overlap each other in planar view. In FIG. 4, a horizontal axis represents the applied voltage (unit: V) of gate electrode 2, and a vertical axis represents the capacitance (unit: pF) of variable capacitive element 100.

When variable capacitive element 100 configured such that the capacitance of only the first capacitor becomes 0.048 pF and such that the capacitances of the first capacitor and the second capacitor become 48 pF is actually measured, the capacitance became 0.052 pF when the applied voltage of the gate electrode 2 is less than the threshold and the capacitance became 41 pF when the applied voltage is greater than or equal to the threshold as illustrated in FIG. 4. In variable capacitive element 100, a modulation factor of the capacitance was 41/0.052=788.5, which was about 800 times.

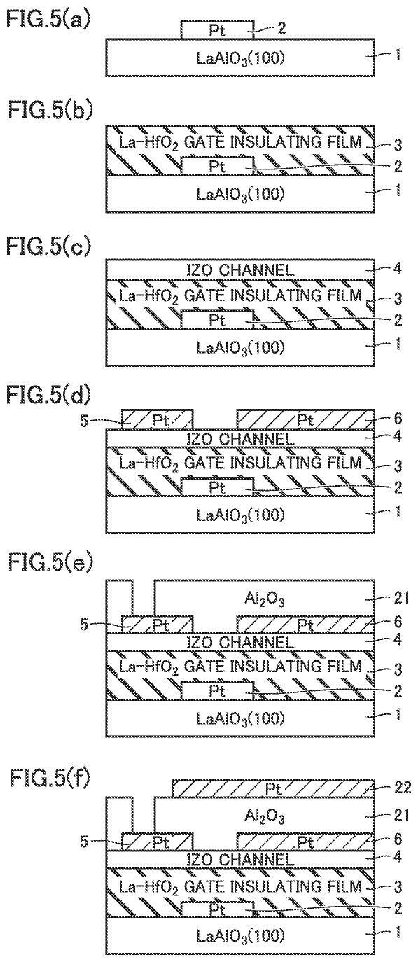

With reference to the drawings, a method of manufacturing variable capacitive element 100 will be described below. FIGS. 5(a) to 5(f) are sectional views illustrating the method for manufacturing the variable capacitive element of the first embodiment. First, in FIG. 5(a), gate electrode 2 of platinum (Pt) having the film thickness of 80 nm is formed on a (100) plane of prepared lanthanum aluminate (LAO) semiconductor substrate 1. Specifically, gate electrode 2 can be formed by forming a photoresist of a predetermined pattern on the (100) plane of the semiconductor substrate 1 using a photolithography technique, and then forming a film of platinum (Pt) by radio-frequency (RF) sputtering, and removing the photoresist by lift-off.

In FIG. 5(b), gate insulating film 3 having the film thickness of 70 nm is formed to overlap the surface of semiconductor substrate 1 on which gate electrode 2 is formed. Specifically, gate insulating film 3 can be formed by spin-coating a La—HfO₂ solution on the surface of semiconductor substrate 1 on which gate electrode 2 is formed using a chemical solution deposition (CSD) method, drying the film at 150° C., and then firing the film at 800° C. in an oxygen atmosphere to crystallize the film.

In FIG. 5©, channel formation film 4 having the film thickness of 25 nm is formed to overlap gate insulating film 3. Specifically, channel formation film 4 can be formed by spin-coating an IZO solution on gate insulating film 3 using the chemical solution deposition method (CSD), drying the film at 150° C., and then firing the film at 500° C. in an oxygen atmosphere to crystallize the film.

In FIG. 5(d), platinum (Pt) source electrode 5 and platinum (Pt) drain electrode 6 each having the thickness of 80 nm are formed on channel formation film 4. Specifically, source electrode 5 and drain electrode 6 can be formed by forming a photoresist of a predetermined pattern on channel formation film 4 using a photolithography technique, then forming the film of platinum (Pt) by radio-frequency (RF) sputtering, and removing the photoresist by lift-off.

In FIG. 5(e), dielectric 21 is formed of the Al₂O₃ film having the film thickness of 500 nm on source electrode 5 and drain electrode 6. Specifically, dielectric 21 can be formed by forming the photoresist of a predetermined pattern on source electrode 5 and drain electrode 6 using the photolithography technique, then forming the Al₂O₃ film by electron cyclotron resonance (ECR) sputtering, and removing the photoresist by lift-off.

In FIG. 5(f), terminal electrode 22 of platinum (Pt) having the film thickness of 80 nm is formed on dielectric 21. Specifically, terminal electrode 22 can be formed by forming the photoresist of the predetermined pattern on dielectric 21 using the photolithography technique, then forming the film of platinum (Pt) by radio-frequency (RF) sputtering, and removing the photoresist by lift-off.

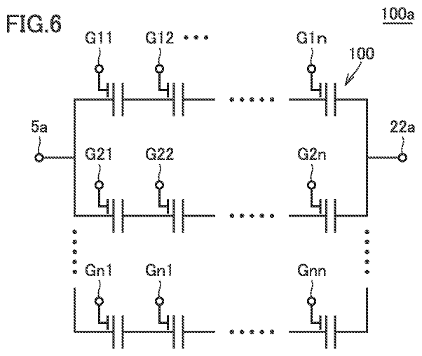

In variable capacitive element 100 described so far, the element in which the capacitance is varied by two values of the capacitance of only the first capacitor and the combined capacitance of the first capacitor and the second capacitor has been described. However, in another exemplary aspect, a multi-valued variable capacitive element can be configured by forming a plurality of variable capacitive elements 100 in a matrix shape on semiconductor substrate 1. FIG. 6 is a circuit diagram illustrating a multi-valued variable capacitive element 100a of the first embodiment. A multi-valued variable electronic element can be similarly configured by forming a plurality of variable electronic elements such as inductors and resistors other than capacitors as the included passive elements in a matrix shape.

FIG. 6 illustrates a circuit diagram of variable capacitive element 100a in which n×n variable capacitive elements 100 in FIG. 3 are connected in the matrix shape. In variable capacitive element 100a of FIG. 6, terminal electrode 5a (e.g., first terminal electrode) and terminals 22a of terminal electrode 22 (e.g., second terminal electrode) are common to n×n variable capacitive elements 100. However, control electrode terminal 2a of each of n×n variable capacitive elements 100 is provided separately, and terminals G11 to Gnn are illustrated in FIG. 6. By supplying signals to terminals G11 to Gnn, a required number of variable capacitive elements 100 can be turned on to obtain a required capacitance, so that variable capacitive element 100a can make variable capacitances multi-valued.

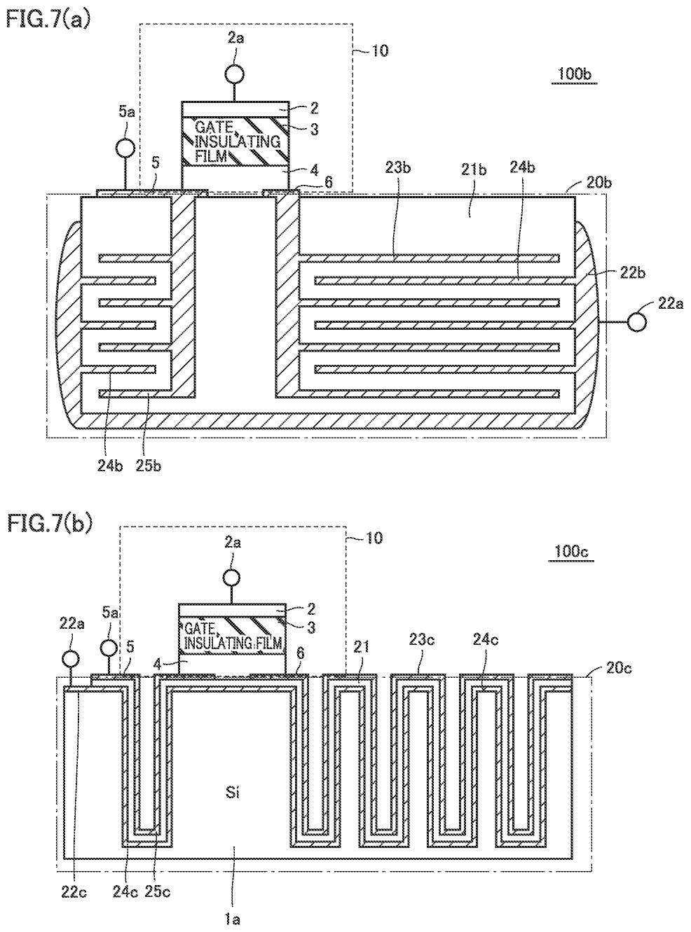

Furthermore, in variable capacitive element 100, the configuration in which element portion 20 is provided on switch portion 10 as illustrated in FIG. 1 has been described. However, element portion 20 may be provided below switch portion 10. Specifically, the variable capacitive element in which element portion 20 is provided under switch portion 10 will be described. FIGS. 7(a) and 7(b) are sectional views illustrating configurations of variable capacitive elements 100b, 100c according to a modification of the first embodiment. It is noted that in variable capacitive elements 100b, 100c of FIGS. 7(a) and 7(b), the same components as those of variable capacitive element 100 in FIG. 1 are denoted by the same reference numerals, and the detailed description thereof will not be repeated.

In particular, FIG. 7(a) illustrates a variable capacitive element 100b in which a multi-layer ceramic capacitor (MLCC) is used for element portion 20b. In variable capacitive element 100b, source electrode 5 and drain electrode 6 are formed on the upper surface of the multi-layer ceramic capacitor of element portion 20b, and channel formation film 4, gate insulating film 3, and gate electrode 2 are formed on source electrode 5 and drain electrode 6 in this order to form switch portion 10.

The multi-layer ceramic capacitor of element portion 20b includes a portion of the first capacitor connected to source electrode 5 and a portion of the second capacitor connected to drain electrode 6. The portion of the first capacitor has a configuration in which a plurality of electrodes 25b connected to source electrode 5 and an electrode 24b connected to a terminal electrode 22b that is an external electrode of the multi-layer ceramic capacitor are laminated with, for example, a dielectric 21b of barium titanate interposed therebetween. In addition, the portion of the second capacitor has a configuration in which a plurality of electrodes 23b connected to drain electrode 6 and electrodes 24b connected to terminal electrode 22b are laminated with dielectric 21b interposed therebetween.

In variable capacitive element 100b, similarly to variable capacitive element 100, when switch portion 10 is in the off state, a gate voltage greater than or equal to the threshold is not applied to gate electrode 2, so that the electron depletion layer exists at the position of channel formation film 4 overlapping gate electrode 2 in planar view and source electrode 5 and drain electrode 6 are not electrically connected. Therefore, the voltage is applied only to dielectric 21b between electrode 25b connected to source electrode 5 and electrode 24b connected to terminal electrode 22b, so that variable capacitive element 100b has the capacitance of only the first capacitor.

On the other hand, when switch portion 10 is in the on state in variable capacitive element 100b, the channel is formed by applying the gate voltage greater than or equal to the threshold to gate electrode 2, and source electrode 5 and drain electrode 6 are electrically connected. Consequently, the voltage is applied to dielectric 21b between electrode 25b connected to source electrode 5 and electrode 23b connected to drain electrode 6, and electrode 24b connected to terminal electrode 22b, so that variable capacitive element 100b has the combined capacitance of the first capacitor and the second capacitor.

In general, it should be appreciated that various configurations such as low temperature co-fired ceramics (LTCC) and high temperature co-fired ceramics (HTCC) can be applied to the portion of the multi-layer ceramic capacitor of element portion 20b.

FIG. 7(b) illustrates a variable capacitive element 100c using a silicon capacitor as an element portion 20c. In variable capacitive element 100c, source electrode 5 and drain electrode 6 are formed on the upper surface of the silicon capacitor of element portion 20c, and channel formation film 4, gate insulating film 3, and gate electrode 2 are formed thereon in this order to configure switch portion 10.

In this exemplary aspect, the silicon capacitor of element portion 20c is formed by a semiconductor process, and is configured of an N+ layer 24c formed by implanting n-type impurity ions into a silicon substrate 1a, a dielectric 21c formed on the surface of N+ layer, and a polysilicon layer 23c that is formed on the surface of dielectric 21c and connected to a polysilicon layer 25c connected to source electrode 5 or drain electrode 6. For example, dielectric 21c is made of an inorganic material such as silicon oxide, silicon nitride, hafnium oxide, hafnium silicate, alumina, or barium titanate formed by a chemical vapor deposition (CVD) method. A plurality of trenches or a plurality of pillars are formed in silicon substrate 1a to form an uneven shape.

As further shown, the silicon capacitor of element portion 20c includes a portion of the first capacitor connected to source electrode 5 and a portion of the second capacitor connected to drain electrode 6. The portion of the first capacitor is configured of a portion of dielectric 21c sandwiched between polysilicon layer 25c connected to source electrode 5 and N+ layer 24c connected to terminal electrode 22c. The portion of the second capacitor is configured of a portion of dielectric 21c sandwiched between polysilicon layer 23c connected to drain electrode 6 and N+ layer 24c connected to terminal electrode 22c.

In variable capacitive element 100c, similarly to variable capacitive element 100, when switch portion 10 is in the off state, the gate voltage greater than or equal to the threshold is not applied to gate electrode 2, so that the electron depletion layer exists at the position of channel formation film 4 overlapping gate electrode 2 in planar view and source electrode 5 and drain electrode 6 are not electrically connected. Therefore, the voltage is applied only to a portion of dielectric 21c sandwiched between polysilicon layer 25c connected to source electrode 5 and N+ layer 24c connected to terminal electrode 22c, so that variable capacitive element 100c has the capacitance of only the first capacitor.

On the other hand, in variable capacitive element 100c, when switch portion 10 is in the on state, the channel is formed by applying the gate voltage greater than or equal to the threshold to gate electrode 2, and source electrode 5 and drain electrode 6 are electrically connected. Accordingly, the voltage is applied to a portion of dielectric 21c sandwiched between polysilicon layer 25c connected to source electrode 5 and polysilicon layer 23c connected to drain electrode 6, and N+ layer 24c connected to terminal electrode 22c, so that variable capacitive element 100c becomes the combined capacitance of the first capacitor and the second capacitor.

In the silicon capacitor of element portion 20c, the capacitance of element portion 20c is increased by providing an uneven portion in silicon substrate 1a. However, in an alternative aspect, dielectric 21c may have a parallel flat plate shape as long as the required capacitance can be secured.

As described above, variable capacitive element 100 of the first embodiment includes switch portion 10 configuring the field effect transistor, and element portion 20 that is electrically connected to switch portion 10 and configures the capacitor (e.g., passive element). Switch portion 10 includes source electrode 5, drain electrode 6, channel formation film 4 that overlaps at least a part of source electrode 5 and a part of drain electrode 6, gate insulating film 3 that overlaps channel formation film 4, and gate electrode 2 that overlaps gate insulating film 3. Element portion 20 includes terminal electrode 5a (e.g., first terminal electrode) electrically connected to source electrode 5, and terminal electrode 22 (e.g., second terminal electrode) that configures the first capacitor (e.g., first passive element) with source electrode 5 and configures the second capacitor (e.g., second passive element) at least with drain electrode 6. Consequently, variable capacitive element 100 is configured to change the capacitance of the capacitor by switching between when element portion 20 is configured by the first capacitor and when element portion 20 is configured by the first capacitor and the second capacitor by turning on and off of switch portion 10. Moreover, switch portion 10 is preferably provided on the upper portion or the lower portion of element portion 20.

Thus, in variable capacitive element 100 of the first embodiment, the first capacitor is configured between source electrode 5 and terminal electrode 22, and the second capacitor is configured between drain electrode 6 and terminal electrode 22, so that the range in which the capacitance of the capacitor can be varied can be widened and the sufficient withstand voltage can be obtained without reducing the capacitance of the capacitor.

Preferably, element portion 20 further includes dielectric 21 provided so as to overlap source electrode 5 and drain electrode 6, dielectric 21 between source electrode 5 and terminal electrode 22 configures the first capacitor serving as the first passive element, and at least dielectric 21 between drain electrode 6 and terminal electrode 22 configures the second capacitor serving as the second passive element.

Moreover, in an exemplary aspect, gate electrode 2 is formed on semiconductor substrate 1, gate insulating film 3 is formed on gate electrode 2 and semiconductor substrate 1, channel formation film 4 is formed on gate insulating film 3, source electrode 5 and drain electrode 6 are formed on channel formation film 4, dielectric 21 is formed on source electrode 5 and drain electrode 6, and terminal electrode 22 is formed on dielectric 21.

### Second Exemplary Embodiment

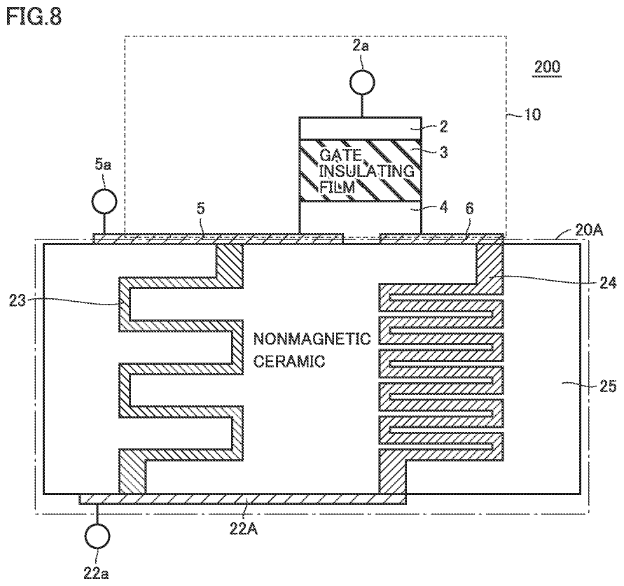

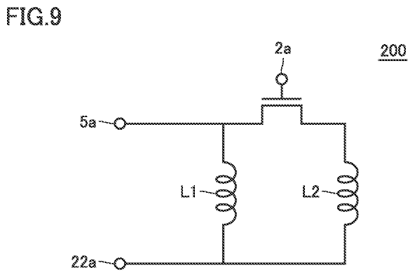

In the variable electronic element of the first embodiment, the included passive element is the capacitor, and the variable capacitive element configured to vary the capacitance has been described. However, the included passive element is not limited to the capacitor. In a variable electronic element according to a second embodiment, the included passive element is an inductor, and a variable inductance element configured to vary inductance will be described with reference to the drawings. FIG. 8 is a sectional view illustrating a configuration of a variable inductance element 200 of the second embodiment. FIG. 9 is a circuit diagram illustrating variable inductance element 200 of the second embodiment. It is noted that in variable inductance element 200 of FIGS. 8 and 9, the same components as those of variable capacitive element 100 of FIGS. 1 and 3 are denoted by the same reference numerals, and a detailed description thereof will not be repeated.

In the exemplary aspect, variable inductance element 200 in FIG. 8 includes switch portion 10 (also referred to as a “switch”) configuring the field effect transistor, and an element portion 20A (also referred to as a “element”) that is electrically connected to switch portion 10 and configures the passive element. In this exemplary aspect, element portion 20A is provided below switch portion 10 in a plan view of variable inductance element 200.

As shown, switch portion 10 includes a gate electrode 2, a gate insulating film 3, a channel formation film 4, a source electrode 5, and a drain electrode 6. In switch portion 10 of FIG. 8, source electrode 5 and drain electrode 6 are formed on the upper surface of element portion 20A, and channel formation film 4, gate insulating film 3, and gate electrode 2 are formed on source electrode 5 and drain electrode 6 in this order to configure switch portion 10.

As illustrated in FIG. 8, in variable inductance element 200, element portion 20A is an inductor, and includes a portion of the first inductor connected to source electrode 5 and a portion of the second inductor connected to drain electrode 6. Moreover, the portion of the first inductor includes a coil electrode 23 connected to source electrode 5 and a terminal electrode 22A that is an external electrode of the inductor. The portion of the second inductor includes a coil electrode 24 connected to drain electrode 6 and terminal electrode 22A that is the external electrode of the inductor. Coil electrode 23 and coil electrode 24 are formed in the same nonmagnetic ceramic 25 in the exemplary aspect. Although terminal electrode 5a (e.g., first terminal electrode) is provided on source electrode 5 in FIG. 8, source electrode 5 itself may be used as terminal electrode 5a. Although control electrode terminal 2a is provided on gate electrode 2 in FIG. 8, gate electrode 2 itself may be used as control electrode terminal 2a. Furthermore, although terminal 22a of terminal electrode 22A is provided on terminal electrode 22A in FIG. 8, terminal electrode 22A itself may be used as terminal 22a.

In variable inductance element 200, similarly to variable capacitive element 100, when switch portion 10 is in the off state, the gate voltage greater than or equal to the threshold is not applied to gate electrode 2, so that the electron depletion layer at the position of channel formation film 4 overlapping gate electrode 2 in planar view and source electrode 5 and drain electrode 6 are not electrically connected. Consequently, the current flows only through coil electrode 24 between source electrode 5 and terminal electrode 22A, so that variable inductance element 200 has the inductance of only the first inductor.

On the other hand, in the variable inductance element 200, when switch portion 10 is in the on state, the channel is formed by applying the gate voltage greater than or equal to the threshold to gate electrode 2, and source electrode 5 and drain electrode 6 are electrically connected. Consequently, the current flows through coil electrode 23 between source electrode 5 and terminal electrode 22A, and coil electrode 24 between drain electrode 6 and terminal electrode 22A, so that variable inductance element 200 has the combined inductance of the first inductor and the second inductor.

As can be seen from the circuit diagram in FIG. 9, in variable inductance element 200, terminal electrode 5a (e.g., first terminal electrode) and terminal 22a of terminal electrode 22A (e.g., second terminal electrode) are connected to the converter circuit or the like, and control electrode terminal 2a varying the inductance is connected to a circuit different from the converter circuit. For this reason, there is a low possibility that the signal applied to control electrode terminal 2a is affected by the signal of the converter circuit.

As described above, in variable inductance element 200 of the second embodiment, the passive element is an inductor, and element portion 20A includes the first inductor that is electrically connected between source electrode 5 and terminal electrode 22A and is configured as the first passive element, and the second inductor that is electrically connected between drain electrode 6 and terminal electrode 22A and is configured as the second passive element.

Thus, in variable inductance element 200 of the second embodiment, the first inductor is configured between source electrode 5 and terminal electrode 22A, and the second inductor is configured between drain electrode 6 and terminal electrode 22A, so that the range in which the inductance of the inductor can be varied can be widened and the sufficient withstand voltage can be obtained without reducing the inductance of the inductor.

According to an exemplary aspect, a multi-valued variable inductance element can be configured by forming a plurality of variable inductance elements 200 in a matrix shape. In addition, by changing coil electrodes 23, 24 in FIG. 8 to resistance elements, the passive element may be used as a variable resistor element as a resistor. Furthermore, the configuration of switch portion 10 described in the first embodiment and the second embodiment is not limited to the described configuration, but for example, may be a silicon MOSFET, a GaNFET, or the like.

### Third Exemplary Embodiment

As described in the first embodiment and the second embodiment, variable capacitive elements 100, 100a and variable inductance element 200 have, due to the configuration thereof, the wide width in which the physical quantity of the passive element can be varied, and have the characteristic in which the sufficient withstand voltage can be obtained without reducing the physical quantity of the passive element. A circuit device including variable capacitive element 100, 100a and variable inductance element 200 using this characteristic will be described below.

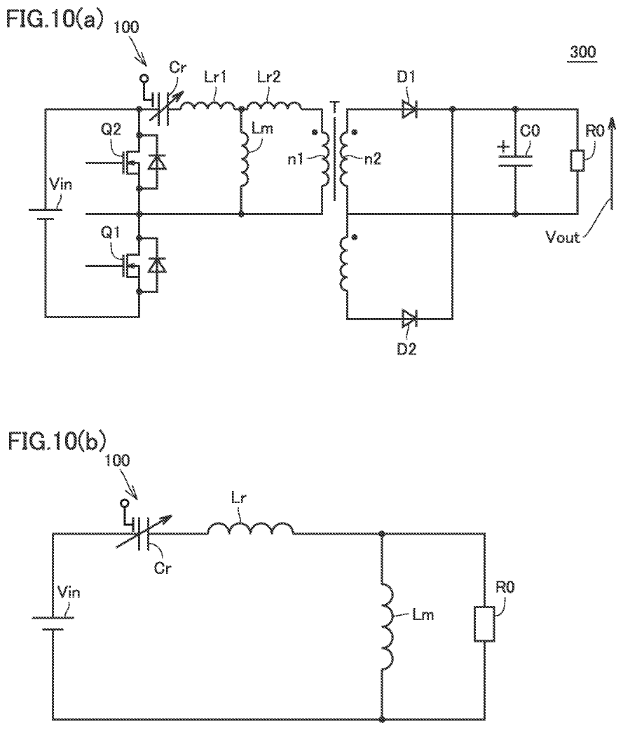

FIG. 10(a) is a circuit diagram illustrating a circuit device according to a third embodiment. FIG. 10(b) is an equivalent circuit in FIG. 10(a). A circuit device 300 in FIG. 10(a) is a circuit that is configured to adjust an output level according to a load variation, and is an LLC resonance converter. In the exemplary aspect, circuit device 300 is the LLC resonant converter configured to convert an input voltage Vin into an output voltage Vout. As shown, circuit device 300 includes switching elements Q1, Q2, a transformer T, a resonance capacitor Cr, leakage inductors Lr, Lr1, Lr2, an excitation inductor Lm, output rectifier diodes D1, D2, and an output capacitor C0. Moreover, output capacitor C0 is connected to a load resistor R0.

An input-output voltage ratio (|Vout/Vin|) of circuit device 300 that is the LLC resonant converter can be expressed as (Equation 1):

$$\begin{matrix}[ Mathematical Formla 1 ] & \\ \frac{\vert Vout \vert}{\vert Vin \vert} = \frac{1}{\sqrt{{( 1 + \frac{1}{S} - \frac{1}{{SF}^{2}} )}^{2} + {{Q}^{2} ( F - \frac{1}{F} )}^{2}}} & ( Equation 1 )\end{matrix}$$

Variables in (Equation 1) are expressed as (Equation 2) and (Equation 3):

$$\begin{matrix}[ Mathematical Formla 2 ] & \\ S = \frac{{L}_{m}}{{L}_{r}} , {f}_{r} = \frac{1}{2 π \sqrt{{L}_{m} {C}_{r}}} , F = \frac{f}{{f}_{r}} & ( Equation 2 )\end{matrix}$$

$$\begin{matrix}[ Mathematical Formla 3 ] & \\ {R}_{a c} = \frac{8}{{π}^{2}} {( \frac{{n}_{1}}{{n}_{2}} )}^{2} {R}_{0} , Q = \frac{\sqrt{\frac{{L}_{r}}{{C}_{r}}}}{{R}_{a c}} & ( Equation 3 )\end{matrix}$$

As can be seen from (Equation 1), the input-output voltage ratio of the LLC resonant converter can be adjusted by modulating a switching frequency f of switching elements Q1, Q2. In the LLC resonant converter, the output voltage (Vout) of the LLC resonant converter is normally adjusted by operating the LLC resonant converter at a frequency greater than or equal to the frequency at which the input-output voltage ratio becomes the maximum value and changing the switching frequency according to a load variation.

For example, when the output voltage (Vout) is lowered, the LLC resonant converter needs to have the switching frequency greater than the frequency at which the input-output voltage ratio becomes a maximum value. However, because the power loss of the LLC resonant converter depends on the switching frequency, there is a problem that the power loss increases when the switching frequency is increased to lower the output voltage (Vout) of the LLC resonant converter.

Accordingly, in circuit device 300, variable capacitive element 100 of the first embodiment is used for resonance capacitor Cr in order to lower the output voltage (Vout) of the LLC resonance converter without increasing the switching frequency. That is, circuit device 300 is configured to lower the output voltage (Vout) without increasing the switching frequency by using variable capacitive element 100 as resonance capacitor Cr.

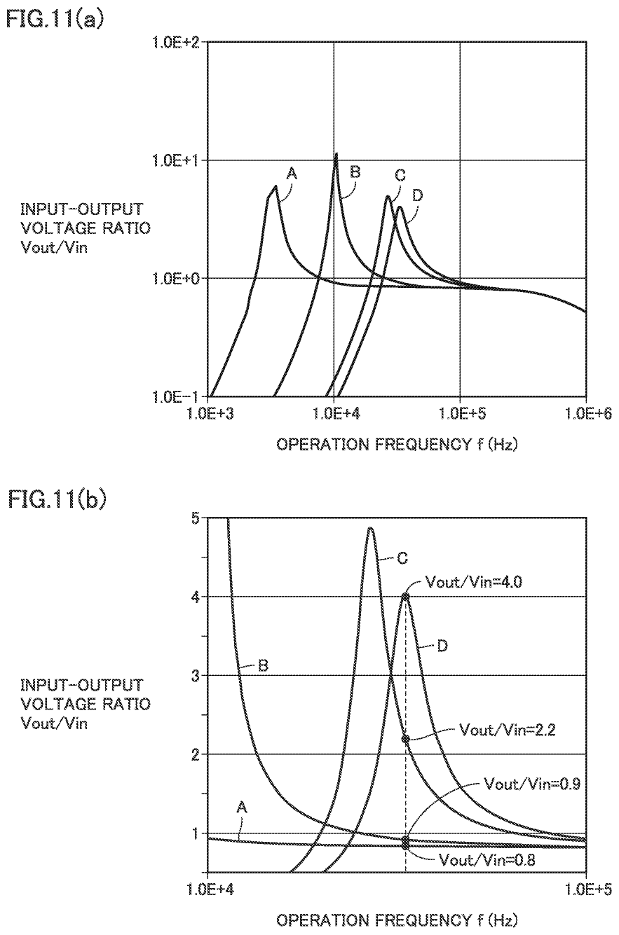

FIGS. 11(a) and 11(b) are graphs illustrating a frequency characteristic of circuit device 300 of the third embodiment. FIG. 11(a) illustrates frequency characteristics of the input-output voltage ratio when the capacitance is 1.5 times, 10 times, and 100 times the capacitance of resonance capacitor Cr (for example, 0.02 μF). FIG. 11(b) is an enlarged view of a part of the graph in FIG. 11(a). In FIGS. 11(a) and 11(b), the horizontal axis represents an operation frequency (unit: Hz), and the vertical axis represents the input-output voltage ratio.

In FIGS. 11(a) and 11(b), the frequency characteristic of the input-output voltage ratio when the capacitance of resonance capacitor Cr is 100 times is a graph A, and the capacitance of resonance capacitor Cr is 10 times is a graph B. In FIGS. 11(a) and 11(b), a graph C illustrates the frequency characteristic of the input-output voltage ratio when the capacitance of the resonance capacitor Cr is increased by 1.5 times, and a graph D illustrates the frequency characteristic of the input-output voltage ratio when the capacitance of resonance capacitor Cr remains.

As illustrated in FIG. 11(b), the input-output voltage ratios illustrated when graphs A to D have the same operation frequency (i.e., the frequency indicated by a broken line) greatly change. Specifically, the input-output voltage ratio of graph D is |Vout/Vin|=4.0, and the input-output voltage ratio of graph C is |Vout/Vin|=2.2. The input-output voltage ratio of graph B is |Vout/Vin|=0.9, and the input-output voltage ratio of graph A is |Vout/Vin|=0.8. That is, by varying the capacitance of resonance capacitor Cr by about 10 times, the input-output voltage ratio can be changed in the range of 4.0 to 0.9 without changing the operating frequency.

As described above, using variable capacitive element 100 as resonance capacitor Cr of circuit device 300, the output voltage (Vout) can be lowered without increasing the power loss. In particular, using multi-valued variable capacitive element 100a as resonance capacitor Cr of circuit device 300, the capacitance of resonance capacitor Cr can be dynamically varied, and the input-output voltage ratio can be changed to multiple stages.

### Fourth Exemplary Embodiment

Soft switching control of the LLC resonant converter will be described below. The LLC resonant converter has a circuit configuration in which the LC resonance is used as illustrated in FIGS. 10(a) and 10(b), and can implement low-loss soft switching by the circuit configuration. In particular, using variable capacitive element 100 as resonance capacitor Cr, for example, even for a switching amplifier (such as a pulse width modulation (PWM) amplifier), the loss at the switching time can be greatly reduced by dynamically changing the capacitance of resonance capacitor Cr.

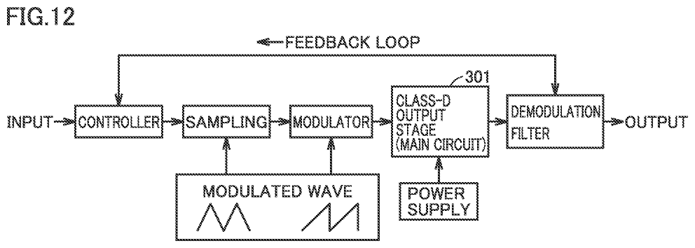

FIG. 12 is a block diagram illustrating a circuit device according to a fourth embodiment. The circuit device in FIG. 12 is a switching amplifier, and uses the LLC resonance converter in which resonance capacitor Cr is used as variable capacitive element 100 for a class-D output stage 301. In class-D output stage 301, by dynamically changing the capacitance value of resonance capacitor Cr (variable capacitive element 100), the capacitive impedance after class-D output stage 301 is reduced to implement the low-loss soft switching.

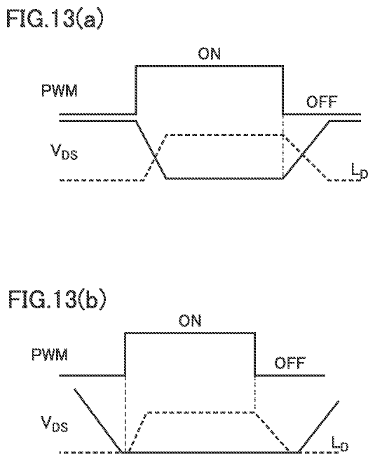

With reference to the drawings, the LLC resonant converter that implements the low-loss soft switching will be further described in detail. FIGS. 13(a) and 13(b) are timing charts illustrating switching timing of the circuit device of the fourth embodiment. In the normal switching, as illustrated in FIG. 13(a), the switching between a voltage V_{DS} and a current I_{D} is generated at the same time, and falling of the current I_{D} is delayed with respect to the off time of the PWM, so that a switching loss (P=IV) is generated at a portion where voltage V_{DS} and current I_{D} intersect with each other. For purposes of this disclosure, the switching in FIG. 13(a) is referred to as hard switching.

On the other hand, in the LLC resonance converter, by vibrating the voltage and the current at the LC resonance frequency, as illustrated in FIG. 13(b), the PWM can be turned on (e.g., zero voltage switching (ZVS)) in the state where voltage V_{DS} is zero. In addition, in the LLC resonance converter, by vibrating the voltage and the current at the LC resonance frequency, the PWM can be turned on (zero current switching (ZCS)) in the state where the current I_{D} is zero. Consequently, the switching loss can be reduced in the LLC resonance converter. For purposes of this disclosure, the switching FIG. 13(b) is referred to as soft switching.

The LLC resonant converter (e.g., circuit device 300 described above) has two resonance frequencies of a resonance frequency fr of resonance capacitor Cr and leakage inductor Lr and a resonance frequency fm of resonance capacitor Cr, leakage inductor Lr, and excitation inductor Lm. In circuit device 300 that is the LLC resonant converter, a condition that the soft switching state is established is determined by the relationship between resonance frequencies fr, fm and switching frequency f. For example, when switching frequency f is lower than resonance frequency fm (f<fm), circuit device 300 satisfies the hard switching condition. However, this condition is not normally used because gain inversion is generated.

In addition, when switching frequency f is larger than resonance frequency fm and is smaller than resonance frequency fr (fm<f<fr), circuit device 300 satisfies the soft switching condition. Furthermore, when switching frequency f is equal to resonance frequency fr (f=fr), circuit device 300 satisfies the hard switching condition. In addition, when switching frequency f is greater than resonance frequency fr (fr<f), circuit device 300 satisfies the soft switching condition.

In circuit device 300 that is the LLC resonance converter, the condition that the soft switching state is satisfied varies depending on the load condition and is determined by conditional expressions illustrated in (Expression 4) and (Expression 5).

$$\begin{matrix}[ Mathematical Formla 4 ] & \\ \vert Vin - Vcr \vert \times \frac{{L}_{m}}{{L}_{r} + {L}_{m}} < Vout \times \frac{{n}_{1}}{{n}_{2}} & ( Equation 4 )\end{matrix}$$

$$\begin{matrix}[ Mathematical Formla 5 ] & \\ \vert Vin - Vcr \vert \times \frac{{L}_{m}}{{L}_{r} + {L}_{m}} > Vout \times \frac{{n}_{1}}{{n}_{2}} & ( Equation 5 )\end{matrix}$$

When the conditional expression of (Expression 4) is satisfied, an output rectifier diode D2 is not conducted, so that the soft switching state is established in circuit device 300. On the other hand, when the conditional expression of (Expression 5) is satisfied, output rectifier diode D2 is conducted, so that the soft switching state is not established in circuit device 300.

For example, when Vout is constant, the condition under which the soft switching is established changes due to a variation in Vin or voltage Vcr of resonance capacitor Cr, so that the condition under which the switching loss increases is generated in circuit device 300. Here, voltage Vcr varies depending on the load condition and the capacitance of resonance capacitor Cr. Consequently, in circuit device 300, the control under the condition that soft switching is satisfied can be performed by varying the capacitance using variable capacitive element 100 as resonance capacitor Cr.

In circuit device 300, variable capacitive element 100 is used for resonance capacitor Cr. As described in the first embodiment, variable capacitive element 100 has a wider variable capacitance range than the conventional variable capacitive element, so that large fluctuations in input voltage Vin and the load condition can be coped with.

As described above, using variable capacitive element 100 for resonance capacitor Cr of circuit device 300, the capacitance of resonance capacitor Cr can be greatly varied, and a wide range of the conditions that the soft switching holds can be secured. In particular, using multi-valued variable capacitive element 100a as resonance capacitor Cr of circuit device 300, the capacitance of resonance capacitor Cr can be dynamically varied, and the condition that the soft switching is satisfied can be adjusted in multiple stages.

It is noted that the same effect can be obtained using the variable inductance element described in the second embodiment for leakage inductor Lr and excitation inductor Lm in addition to the use of variable capacitive element 100 for resonance capacitor Cr of circuit device 300. In addition, the circuit device configured to adjust the condition that the soft switching is satisfied by varying resonance capacitor Cr or the like is not limited to circuit device 300 that is the LLC resonance converter, and can also be applied to circuit devices of various resonance systems such as a current resonance circuit, a voltage resonance circuit, a multiple resonance circuit, a series resonance circuit, and a parallel resonance circuit.

### Fifth Exemplary Embodiment

A circuit configuration in which the variable capacitive element described in the first embodiment and the variable inductance element described in the second embodiment are applied to a multi-band wireless communication terminal will be described below. With the spread of the Internet of Things (IoT), in a wireless communication system, it is desired to provide an optimal communication characteristic according to each condition such as a place to be used, time, available frequency, and a required signal transmission speed. For example, in the wireless communication system, a very wide frequency band of about several 10 MHz to 5 GHz is required to be used in one wireless communication terminal in order to communicate large-capacity and high-density data.

For this reason, in the wireless communication terminal, a plurality of RF circuits that need to be multi-band and correspond to each frequency are required to be provided, and the RF circuit to be used is required to be appropriately switched. However, when the plurality of RF circuits are provided, the wireless communication terminal increases in a circuit scale and the number of components, and it becomes difficult to reduce the size and cost of the terminal.

Accordingly, in the wireless communication terminal, the circuit scale and the number of components are required to be reduced by sharing a circuit block for a plurality of frequencies. However, when the circuit block is shared for the plurality of frequencies, signal reflection between the circuit blocks is required to be prevented, and impedance matching is required to be performed according to each frequency. In addition, in order to share the reception antenna of the wireless communication terminal, the resonance frequency of the antenna is required to be significantly modulated. In the wireless communication terminal, when the capacitance value of the capacitor is varied in order to perform the impedance matching and modulation of the resonance frequency, a plurality of frequency bands can be covered while the circuit scale and the number of components are reduced.

Variable capacitive element 100 of the first embodiment described above has the wider range of capacitance that can be varied than the conventional variable capacitive element. Consequently, the wireless communication terminal using variable capacitive element 100 can cover the wide frequency band. In addition, the capacitance value of variable capacitive element 100 is switched by the voltage applied to the control electrode terminal 2a, so that the capacitance value does not change nonlinearly (gently) with respect to the voltage unlike the conventional variable capacitive element. For this reason, in the wireless communication terminal using variable capacitive element 100, a distortion signal is not generated, and a disturbance signal is not generated for other frequencies.

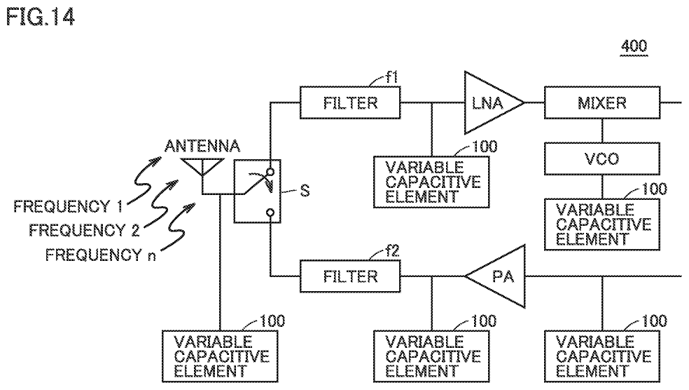

FIG. 14 is a block diagram illustrating a circuit device 400 according to a fifth embodiment. Circuit device 400 is a communication circuit block provided in the wireless communication terminal, and is configured for sharing a plurality of frequencies. For this reason, in circuit device 400, variable capacitive element 100 is applied to the capacitor in which the capacitance value is required to be variable in order to perform the impedance matching and the modulation of the resonance frequency.

In circuit device 400, variable capacitive element 100 is configured to vary the capacitance in the range of 10 times to 1000 times, so that the impedance matching and the modulation of the resonance frequency can be performed in the wider range to cover a wider reception frequency band. Furthermore, in circuit device 400, variable capacitive element 100 digitally varies the capacitance, so that the distortion signal can be prevented. Consequently, using circuit device 400, the multi-band wireless communication terminal configured to cover the plurality of frequency bands can be implemented while the circuit scale and the number of components are reduced. Multi-valued variable capacitive element 100a may be used for the capacitor of circuit device 400.

### Sixth Exemplary Embodiment

A configuration in which the loss is reduced using the variable capacitive element described in the first embodiment in a DC circuit breaker will be described. The configuration of the DC circuit breaker can be similarly applied to switches, connection devices, and arc prevention devices of various power supply circuits. In addition, for example, the DC circuit breaker can be used in a DC power supply device such as an energy harvesting device such as solar power generation, a fuel cell, or a lithium ion cell.

In the DC circuit breaker, a power semiconductor switch using silicon carbide (SiC) or gallium nitride (GaN) capable of high-withstand voltage, high temperature operation, and high speed operation as compared with the MOSFET is expected to be used instead of the metal contact. However, the switching of about several 100 V to several 10 A is possible when a power semiconductor switch is used in the DC circuit breaker instead of the metal contact, but there is a problem that an energization loss due to heat generation at the time of energization of the semiconductor becomes very large and the provision of a cooling device is required.

On the other hand, when the metal contact is used for the DC circuit breaker, the energization loss can be reduced, but the loss at the time of off becomes very large because arc discharge is generated at the time of interruption. Accordingly, there has been proposed a DC circuit breaker using a hybrid switch circuit in which the metal contact with the small energization loss is energized at the time of on, and the current is commutated to a semiconductor switch of the MOSFET only at the time of off to prevent the arc discharge. For example, the hybrid switch circuit is described in “Smart Switch with Semiconductor Device (Hybrid Switching/Connecting device)”, to Ryuichi Shimada, Journal of the Power Electronics Society of Japan, March 2017, Vol. 42, p. 53-57.

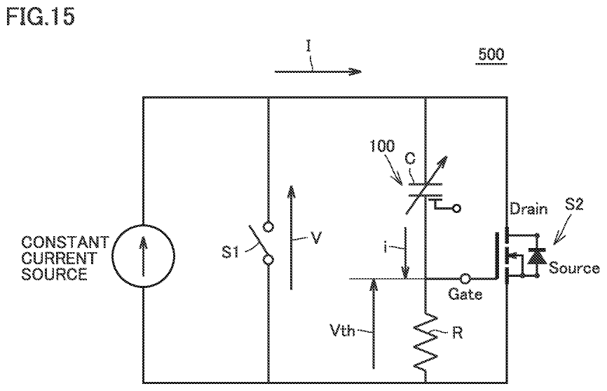

FIG. 15 is a circuit diagram of a circuit device 500 according to a sixth embodiment. Circuit device 500 is a hybrid switch circuit used for the DC circuit breaker, and includes a metal contact S1 and a semiconductor switch S2 of the MOSFET. In circuit device 500, since metal contact S1 can be opened and closed without arc discharge, there is an advantage that no contact exhaustion, a long life, and high-speed current cut off can be performed, and the noise due to the arc discharge is not generated.

In circuit device 500, the current flows through metal contact S1 when metal contact S1 is on, and when metal contact S1 is off, semiconductor switch S2 is turned on at threshold voltage Vth of the MOSFET, and the current flows through semiconductor switch S2. After metal contact S1 is turned off, re-electromotive voltage V of metal contact S1 is given by (Equation 6). Vth is the threshold voltage of the MOSFET, and t is time.

$$\begin{matrix}[ Mathematical Formla 6 ] & \\ V = Vth + \frac{Vth}{R C} \times t & ( Equation 6 )\end{matrix}$$

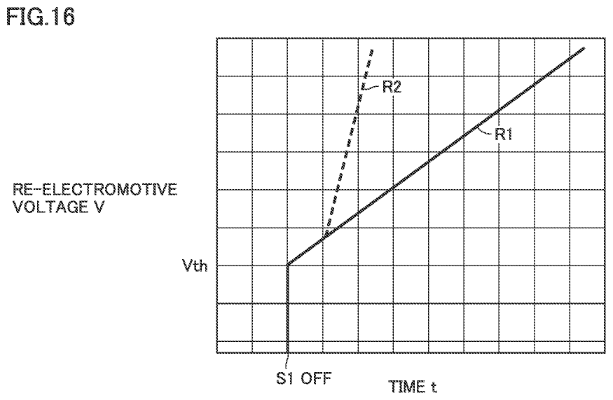

Re-electromotive voltage V of metal contact S1 increases linearly with respect to time t, but energy consumed at this time becomes a circuit loss. FIG. 16 is a graph illustrating a switching characteristic of the circuit device 500 of the sixth embodiment. In FIG. 16, the horizontal axis represents time t, and the vertical axis represents re-electromotive voltage V. As indicated by a graph R1 in FIG. 16, after metal contact S1 is turned off, re-electromotive voltage V of metal contact S1 increases linearly with respect to time t.

For this reason, in order to reduce the circuit loss, desirably re-electromotive voltage V of metal contact S1 rises as sharply as possible after metal contact S1 is turned off. As indicated by graph R2 in FIG. 16, the circuit loss can be reduced by rapidly increasing re-electromotive voltage V of metal contact S1. As can be seen from (Equation 6), the smaller the capacitance of capacitor C, the steeper re-electromotive voltage V rises, and the circuit loss can be reduced. On the other hand, when metal contact S1 is on (and immediately after metal contact S1 is turned off), the capacitance of capacitor C is required to set to the relatively large capacitance (for example, several 10 nF) in order to absorb the electric charge that generates the arc discharge.

Accordingly, in circuit device 500, as illustrated in FIG. 15, the variable capacitive element described in the first embodiment above is used for capacitor C, such that the capacitance of capacitor C can be largely varied between the on state and the off state of metal contact S1. Consequently, the DC circuit breaker in which the circuit loss is very low while the arc discharge is prevented is implemented in circuit device 500. In the variable capacitive element of the first embodiment, the high-withstand voltage can be obtained while the capacitance is varied in the wide range that has been difficult to be implemented in the conventional variable capacitive element. Multi-valued variable capacitive element 100a may be used for capacitor C of circuit device 500.

### Seventh Exemplary Embodiment

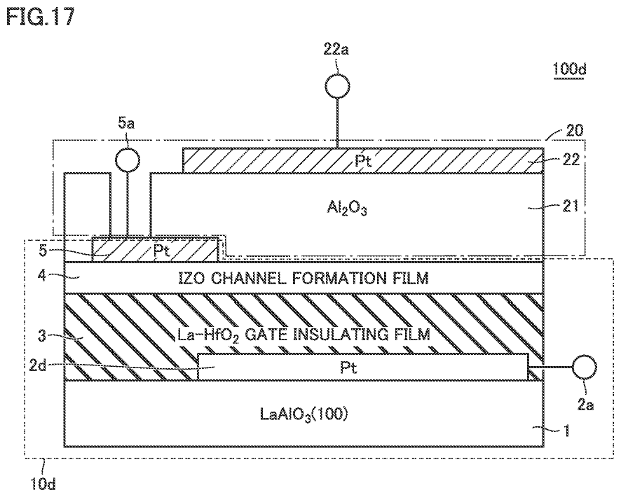

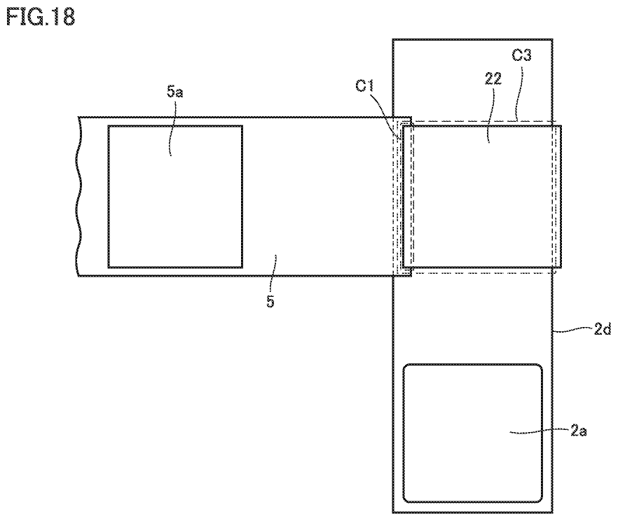

As described above in the first embodiment, switch portion 10 includes gate electrode 2, gate insulating film 3, channel formation film 4, source electrode 5, and drain electrode 6. Among them, drain electrode 6 is a floating electrode, and configures a switch portion in which drain electrode 6 is not provided. In a variable electronic element according to a seventh embodiment, a configuration in which the drain electrode as the floating electrode is not provided will be described with reference to the drawings. FIG. 17 is a sectional view illustrating a configuration of a variable capacitive element 100d of the seventh embodiment. FIG. 18 is a plan view illustrating the configuration of variable capacitive element 100d of the seventh embodiment. In variable capacitive element 100d of FIGS. 17 and 18, the same components as those of variable capacitive element 100 in FIGS. 1 and 2 are denoted by the same reference numerals, and the detailed description thereof will not be repeated.

A variable capacitive element 100d in FIG. 17 includes a switch portion 10d (also referred to as a “switch”) configuring the field effect transistor formed on semiconductor substrate 1, and element portion 20 (also referred to as a “element”) that is electrically connected to switch portion 10d and configures the passive element. As further shown, element portion 20 is provided above switch portion 10d.

Switch portion 10d includes a gate electrode 2d, gate insulating film 3, channel formation film 4, and source electrode 5. In switch portion 10d of FIG. 17, gate electrode 2d is formed on semiconductor substrate 1, gate insulating film 3 and channel formation film 4 are sequentially formed so as to overlap gate electrode 2d, and source electrode 5 is formed on gate insulating film 3 and channel formation film 4.

In switch portion 10d, the drain electrode is not provided, but gate electrode 2d is widened as illustrated in FIG. 18, and a majority of terminal electrode 22 overlaps gate electrode 2d in planar view. Therefore, in variable capacitive element 100d, when switch portion 10d is turned on, the gate voltage is applied to gate electrode 2d, and the channel charges are generated in a portion of channel formation film 4 overlapping gate electrode 2d in planar view. In variable capacitive element 100d, the capacitance is formed by applying the voltage between a portion of source electrode 5 and channel formation film 4, and terminal electrode 22 opposite the portion.

On the other hand, when switch portion 10d is in the off state, no gate voltage is applied to gate electrode 2d in variable capacitive element 100d, so that no channel charge is generated in channel formation film 4. For this reason, because voltage is applied only between source electrode 5 and terminal electrode 22 opposite to source electrode 5, variable capacitive element 100d has the capacitance of only the first capacitor.

According to the exemplary aspect, element portion 20 comprises the first capacitor (e.g., first passive element) between source electrode 5 and terminal electrode 22, and configures the second capacitor (e.g., second passive element) between gate electrode 2d and terminal electrode 22. Specifically, as illustrated in FIG. 18, the first capacitor is a portion C1 where source electrode 5 and terminal electrode 22 overlap each other in planar view. The second capacitor is a portion C3 where gate electrode 2d and terminal electrode 22 overlap each other in planar view.

Even in variable capacitive element 100d, by turning on and off switch portion 10d, the capacitance of the capacitor can be varied by switching between the configuration in which the first capacitor element is used as element portion 20 and the configuration in which the first capacitor element and the second capacitor element are used as element portion 20. Even variable capacitive element 100d is the variable capacitive element that is divided into switch portion 10d that performs the on and off operation by the voltage applied to gate electrode 2d (e.g., control electrode terminal 2a), terminal electrode 5a (e.g., first terminal electrode), element portion 20 that operates with terminal electrode 22 (e.g., second terminal electrode), and operates with three terminals.

However, in variable capacitive element 100d, because the capacitance of the second capacitor element can be changed by the channel charge generated in channel formation film 4 without providing the drain electrode, the capacitance of the second capacitor element can be continuously varied by the voltage applied to gate electrode 2d. In addition, in variable capacitive element 100d, the residual charge in the floating electrode is reduced at the time of the on and off operation of switch portion 10d by adopting the configuration in which the drain electrode that is the floating electrode is not provided, so that the potential of the capacitor can be stabilized or the failure due to short-circuiting can be reduced. Furthermore, in variable capacitive element 100d, the drain electrode that is the floating electrode is not provided, the conductivity can be varied stepwise in the wide region of channel formation film 4 according to the level of the gate voltage to be applied, so that the capacitance of the capacitor can be changed more continuously.

As described above, variable capacitive element 100d of the seventh embodiment uses the portion C3 where gate electrode 2d and channel formation film 4 overlap each other in planar view instead of the drain electrode. The second capacitor element is formed between portion C3 and terminal electrode 22. Thus, variable capacitive element 100d is configured to continuously vary the capacitance of the second capacitor element.

In variable capacitive element 100d, the configuration in which element portion 20 is provided on switch portion 10d as illustrated in FIG. 17 has been described, but it is noted that element portion 20 can be provided under switch portion 10d in an alternative aspect. In addition, a multi-valued variable electronic element can be similarly configured by forming a plurality of variable capacitive elements 100d in a matrix shape. Furthermore, the configuration of variable capacitive element 100d can be applied to a variable electronic element other than a capacitor, such as an inductor or a resistor.

### Eighth Exemplary Embodiment

In variable capacitive element 100 of the first embodiment described above, terminal electrode 22 is also formed on the channel region formed between source electrode 5 and drain electrode 6. Accordingly, variable capacitive element 100 can affect the on and off state of switch portion 10 by the voltage applied to terminal 22a of terminal electrode 22. That is, in variable capacitive element 100, there has been a risk that the capacitance value fluctuates due to a signal between terminal electrode 5a and terminal 22a of terminal electrode 22.

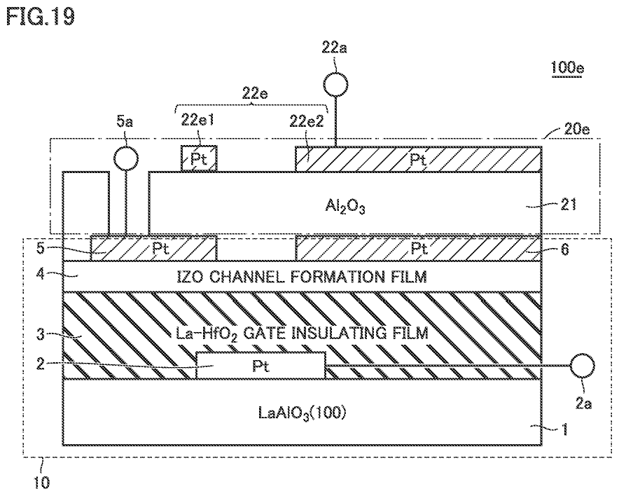

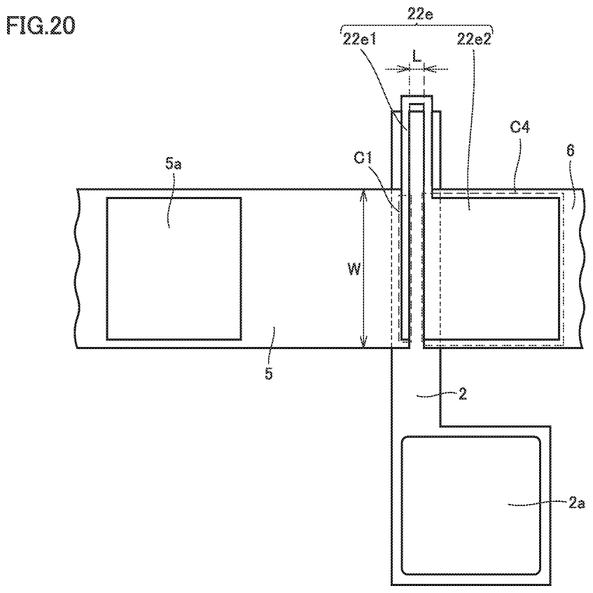

Accordingly, in a variable electronic element according to an eighth embodiment, a configuration in which the capacitance value is less likely to fluctuate by the signal between the first terminal electrode and the second terminal electrode will be described with reference to the drawings. FIG. 19 is a sectional view illustrating a configuration of a variable capacitive element 100e of the eighth embodiment. FIG. 20 is a plan view illustrating the configuration of variable capacitive element 100e of the eighth embodiment. It is noted that in variable capacitive element 100e of FIGS. 19 and 20, the same components as those of variable capacitive element 100 in FIGS. 1 and 2 are denoted by the same reference numerals, and the detailed description thereof will not be repeated.

Variable capacitive element 100e in FIG. 19 includes a switch portion 10 (also referred to as a “switch”) configuring a field effect transistor formed on a semiconductor substrate 1 and an element portion 20e (also referred to as a “element”) that is electrically connected to switch portion 10 and configures the passive element. As further shown, element portion 20e is provided above switch portion 10 in a plan view according to the exemplary aspect.

Moreover, element portion 20e includes the Al₂O₃ film of dielectric 21 and a terminal electrode 22e (e.g., second terminal electrode) of platinum (Pt) formed to overlap dielectric 21. As illustrated in FIG. 20, terminal electrode 22e is formed in a pattern avoiding the channel region formed between source electrode 5 and drain electrode 6. For this reason, in the sectional view of FIG. 19, a terminal electrode 22e1 formed on the upper portion of source electrode 5 and a terminal electrode 22e2 formed on the upper portion of drain electrode 6 are illustrated separately.

According to the exemplary aspect, element portion 20e comprises the first capacitor (e.g., first passive element) between source electrode 5 and terminal electrode 22e1, and configures the second capacitor (e.g., second passive element) between drain electrode 6 and terminal electrode 22e2. As illustrated in FIG. 20, the first capacitor is portion C1 where source electrode 5 and terminal electrode 22e1 overlap each other in planar view. The second capacitor is a portion C4 where drain electrode 6 and terminal electrode 22e2 overlap each other in planar view.

In variable capacitive element 100e, when switch portion 10 is in the off state, the gate voltage greater than or equal to the threshold is not applied to gate electrode 2, so that the electron depletion layer exists at the position of channel formation film 4 overlapping gate electrode 2 in planar view and source electrode 5 and drain electrode 6 are not electrically connected. For this reason, the voltage is applied only between source electrode 5 and the portion (i.e., a first region) of terminal electrode 22e1 opposite to source electrode 5, so that variable capacitive element 100e has the capacitance of only the first capacitor.

However, in variable capacitive element 100e, when switch portion 10 is in the on state, the channel is formed by applying the gate voltage equal to greater than or equal to the threshold to gate electrode 2, and source electrode 5 and drain electrode 6 are electrically connected. For this reason, the voltage is applied between source electrode 5 and drain electrode 6, and terminal electrode 22e (i.e., first and second regions) opposite to each other, so that the variable capacitive element 100e has the combined capacitance of the first capacitor and the second capacitor. At this point, in terminal electrode 22e, a portion overlapping source electrode 5 in planar view is referred to as the first region (e.g., terminal electrode 22e1), and a portion overlapping the drain electrode in planar view is referred to as the second region (e.g., terminal electrode 22e2).

Because terminal electrode 22e does not overlap the channel region formed between source electrode 5 and drain electrode 6 in planar view, the capacitance of variable capacitive element 100e is smaller than that of variable capacitive element 100 in FIG. 1 when switch portion 10 is in the on state. However, as described above, in variable capacitive element 100e, the capacitance value is less likely to fluctuate due to the signal between terminal electrode 5a (e.g., first terminal electrode) and terminal 22a of terminal electrode 22 (e.g., second terminal electrode). As a matter of course, in variable capacitive element 100e, even when terminal electrode 22e is not formed in the pattern that bypasses the entire portion of the channel region formed between source electrode 5 and drain electrode 6 as illustrated in FIG. 20, the variation in the capacitance value due to the signal between the first terminal electrode and the second terminal electrode can be prevented even in the pattern overlapping a part of the channel region.

As described above, in variable capacitive element 100e, terminal electrode 22e has the first region overlapping source electrode 5 in planar view and the second region overlapping drain electrode 6 in planar view, and the first region and the second region are electrically connected while bypassing at least one part of the channel region formed between source electrode 5 and drain electrode 6. At this point, terminal electrode 22e bypasses at least one part of the channel region formed between source electrode 5 and drain electrode 6 means that the terminal electrode has a portion that does not overlap at least one part of the channel region in planar view.

In variable capacitive element 100e, the configuration in which element portion 20e is provided on switch portion 10 as illustrated in FIG. 19 has been described. However, element portion 20e may be provided below switch portion 10. In addition, a multi-valued variable electronic element may be similarly configured by forming a plurality of variable capacitive elements 100e in a matrix shape. Furthermore, the configuration of variable capacitive element 100e may be applied to a variable electronic element such as an inductor or a resistor other than the capacitor.

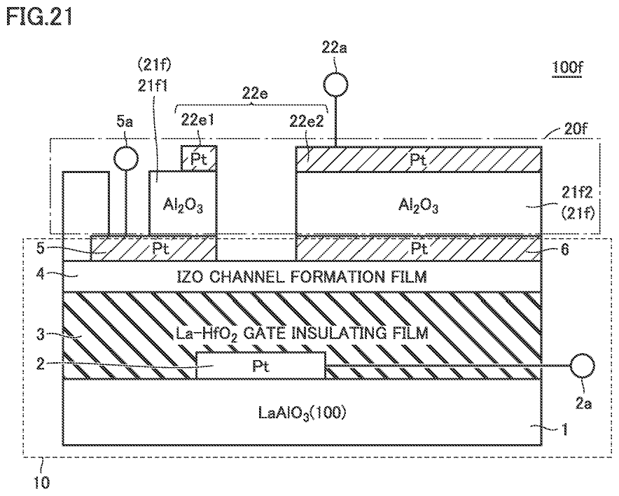

In a variable capacitive element 100f according to the eighth embodiment, it has been described that the terminal electrode 22e is formed in the pattern avoiding the channel region formed between source electrode 5 and drain electrode 6. However, the dielectric may also be formed in the pattern avoiding the channel region in accordance with the pattern of the terminal electrode. Specifically, FIG. 21 is a sectional view illustrating a configuration of a variable capacitive element 100f according to a modification of the eighth embodiment. In variable capacitive element 100f of FIG. 21, the same components as those of variable capacitive element 100e in FIGS. 19 and 20 are denoted by the same reference numerals, and the detailed description thereof will not be repeated.

A variable capacitive element 100f illustrated in FIG. 21 includes a switch portion 10 configuring the field effect transistor formed on semiconductor substrate 1, and an element portion 20f electrically connected to switch portion 10 and configuring the passive element. Element portion 20f is provided above switch portion 10.

According to the exemplary aspect, element portion 20f includes the Al₂O₃ film of a dielectric 21f and terminal electrode 22e (e.g., second terminal electrode) of platinum (Pt) formed to overlap dielectric 21f. As illustrated in FIG. 20, terminal electrode 22e is formed in a pattern avoiding the channel region formed between source electrode 5 and drain electrode 6. Dielectric 21f is formed in the pattern avoiding the channel region formed between source electrode 5 and drain electrode 6 in accordance with the pattern of terminal electrode 22e. Therefore, in the sectional view of FIG. 21, a dielectric 21f1 and terminal electrode 22e1 formed on the upper portion of source electrode 5 are illustrated separately from a dielectric 21f2 and terminal electrode 22e2 formed on the upper portion of drain electrode 6. When terminal electrode 22e bypasses at least one part of the channel region formed between source electrode 5 and drain electrode 6, dielectric 21f is formed so as to avoid at least one part of the channel region formed between source electrode 5 and drain electrode 6 in accordance with the pattern of terminal electrode 22e.

(Modification of the Exemplary Aspect)

In general, for variable capacitive elements 100,100a to 100d and the variable inductance element 200 described in the above-described embodiments, the Q value (Q=1/ωCR) of switch portion 10 is required to be improved in order to improve the variable speed, namely, the switching speed. Here, ω is each frequency. That is, the switching speed can be improved by reducing parasitic resistance R and capacitor C (parasitic capacitance).

Parasitic resistance R corresponds to the series resistance of channel formation film 4 and is given by R=ρ(L/(Wt)). Here, ρ is a material-specific resistivity of channel formation film 4, L is a channel length, W is a channel width, and t is a film thickness of channel formation film 4.

As described above, parasitic resistance R depends on the value of channel length L/channel width W. Consequently, the Q factor can be improved by increasing channel width W with respect to channel length L. In switch portion 10, source electrode 5 and drain electrode 6 are provided on channel formation film 4 as illustrated in FIG. 2, so that channel length L and channel width W can be easily changed by the device design.

On the other hand, capacitor C (parasitic capacitance) corresponds to the capacitance of gate insulating film 3 of switch portion 10, is proportional to the relative dielectric constant of gate insulating film 3, and is inversely proportional to the film thickness. Consequently, switch portion 10 has the structure separated from element portion 20, so that capacitor C (parasitic capacitance) can be individually adjusted.

For example, in variable capacitive element 100 of the first embodiment, when channel length L is 10 μm, when channel width W is 100 μm, when parasitic resistance R is 1 kΩ, and when capacitor C (parasitic capacitance) is 10 pF, the Q value is 0.02 at 1 MHz. Here, when channel length L is miniaturized to 1 μm, when channel width W is 1000 μm, when the film thickness of gate insulating film 3 is 10 times (7000 μm), and when the relative permittivity of gate insulating film 3 is ⅕ (about 40˜50), the Q value is 100. Consequently, the switching speed of switch portion 10 can be improved to 5000 times.

In the above-described embodiment, it has been described that the IZO film is used for channel formation film 4, but this is an example, and another film such as an ITO film may be used. In addition, in the above-described embodiment, it has been described that the La—HfO₂ film is used for gate insulating film 3, but this is an example, and another film such as a Ce—HfO₂ film may be used.

In the variable electronic element described in the above-described embodiment, for example, in variable capacitive element 100, channel formation film 4 is formed below source electrode 5 and drain electrode 6 as illustrated in FIG. 1 (e.g., a top contact structure). The top contact structure is a structure in which the upper side of channel formation film 4 is in contact with source electrode 5 and drain electrode 6 when viewed from the side of gate electrode 2. However, it is noted that the exemplary aspects of the present invention are not limited thereto, and in the variable electronic element, for example, channel formation film 4 may be formed on the upper side of source electrode 5 and drain electrode 6 in variable capacitive element 100 (e.g., a bottom contact structure). The bottom contact structure is a structure that is in contact with source electrode 5 and drain electrode 6 on the lower side of channel formation film 4 when viewed from the side of gate electrode 2.

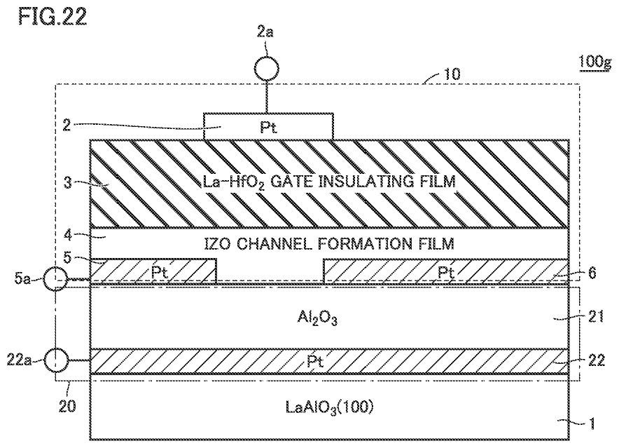

In the variable electronic element described in the above-described embodiment, for example, as illustrated in FIG. 1, the bottom gate structure in which gate electrode 2 is formed on semiconductor substrate 1, gate insulating film 3 and channel formation film 4 are sequentially formed so as to overlap gate electrode 2, and source electrode 5 and drain electrode 6 are respectively formed on gate insulating film 3 and channel formation film 4 is adopted in variable capacitive element 100. However, the exemplary aspects of the present invention are not limited thereto, but the variable electronic element can utilize a top gate structure in an alternative exemplary aspect. FIG. 22 is a sectional view illustrating a configuration of a variable capacitive element 100g according to a modification. In variable capacitive element 100g, as illustrated in FIG. 22, element portion 20 is provided below switch portion 10. Switch portion 10 adopts the top gate structure in which source electrode 5 and drain electrode 6 are formed on dielectric 21, channel formation film 4 and gate insulating film 3 are sequentially formed so as to overlap source electrode 5 and drain electrode 6, and gate electrode 2 is formed on gate insulating film 3. In variable capacitive element 100g of FIG. 22, the same components as those of the variable capacitive element 100 in FIG. 1 are denoted by the same reference numerals, and the detailed description thereof will not be repeated.

In variable capacitive element 100g having the top gate structure, the top contact structure in which source electrode 5 and drain electrode 6 are in contact with each other on the upper side of channel formation film 4 when viewed from the side of gate electrode 2 is adopted as illustrated in FIG. 22. However, the exemplary aspects of the present invention are not limited thereto, and the bottom contact structure in contact with source electrode 5 and drain electrode 6 on the lower side of channel formation film 4 when viewed from the side of gate electrode 2 may be adopted even in variable capacitive element 100g having the top gate structure.

Moreover, materials that can be used for gate insulating film 3 and dielectric 21 will be collectively listed below. It should be appreciated that the material is not limited to the following description:

Amorphous or polycrystalline metal oxide such as SiO₂, Al₂O₃, HfO₂, ZrO₂, La₂O₃, or Ta₂O₅
Nitride film such as SiN, Si₃N₄, or SiON
Ferroelectric films obtained by doping the ferroelectric HfO₂ and HfO₂ with at least one trivalent, tetravalent, or pentavalent metal atom such as Si, Ce, Y, Zr, Bi, Ni, Ta, or La, a ferroelectric material using PbTiO₃ as a mother crystal, a ferroelectric material using BaTiO₃ as a mother crystal, a ferroelectric material having a Bi layered structure, a metal oxide having a perovskite type crystal, a metal oxide having a pyrochlore type crystal, an organic ferroelectric material, and other resin materials (polyimide, acryl, epoxy, polypropylene, polyester, polyethylene terephthalate, polyethylene naphthalate, polyphenylene sulfide, polylactic acid, and the like)

Moreover, materials that can be used for channel formation film 4 are collectively listed below. It should be appreciated that the material is not limited to the following description:
In—O, In—Sn—O, In—Zn—O, In—Sn—Zn—O, In—Ga—Zn—O, In—Ga—O, Ga—O, Zn—O, Al—Zn—O, Sn—O, Ti—O-based n-type oxide semiconductor
Cu—O, Sn—O, Zn—O-based p-type oxide semiconductor
Cu—Sn—I-based amorphous p-type oxide semiconductor
Si semiconductor such as n-type Si, p-type Si, or SiC
Nitride semiconductors such as GaN
Graphene and transition metal chalcogenide-based two-dimensional conductive material
Perovskite-type conductive material such as LaNiO₃, BaSnO₃, and SrTiO₃

In variable capacitive elements 100 to 100g described in the above-described embodiments, when a ferroelectric film such as a La—HfO₂ film is used for gate insulating film 3, the configuration of the ferroelectric gate transistor is included. For this reason, variable capacitive elements 100 to 100g have memory characteristics derived from the configuration of the ferroelectric gate transistor. Specifically, in variable capacitive element 100 of FIG. 1, a capacitance value Cₒₙ generated when an on voltage (for example, +10 V) is applied to gate electrode 2 to configure the capacitor between terminal electrode 22 and drain electrode 6 can be held only by applying a holding voltage of 0 (zero) V or a small constant value (for example, −1.0 V) to gate electrode 2. Similarly, in variable capacitive element 100, a capacitance value C_{off} generated when an off voltage (for example, −10 V) is applied to gate electrode 2 and the capacitor is not configured between terminal electrode 22 and drain electrode 6 can be held only by applying the holding voltage of 0 (zero) V or the small constant value (For example, −1.0 V) to gate electrode 2.

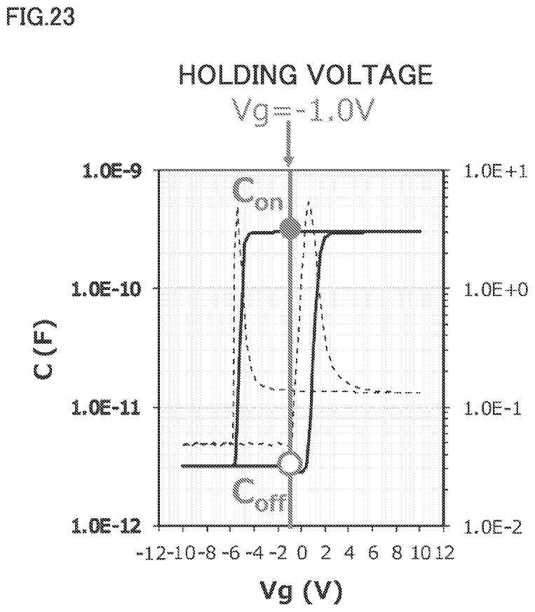

FIG. 23 is a view illustrating a relationship between the capacitance and the holding voltage of the variable capacitive element. In FIG. 23, the horizontal axis represents the gate voltage, and the vertical axis represents the capacitance. When the ferroelectric gate transistor is configured using the ferroelectric film such as the La—HfO₂ film for gate insulating film 3, as illustrated in FIG. 23, the change in capacitance value C generated between terminal electrode 22 and drain electrode 6 with respect to gate voltage Vg applied to gate electrode 2 becomes a hysteresis curve. As shown in FIG. 23, capacitance value Cₒₙ and capacitance value C_{off} can be maintained by applying the holding voltage of −1.0 V to gate electrode 2.

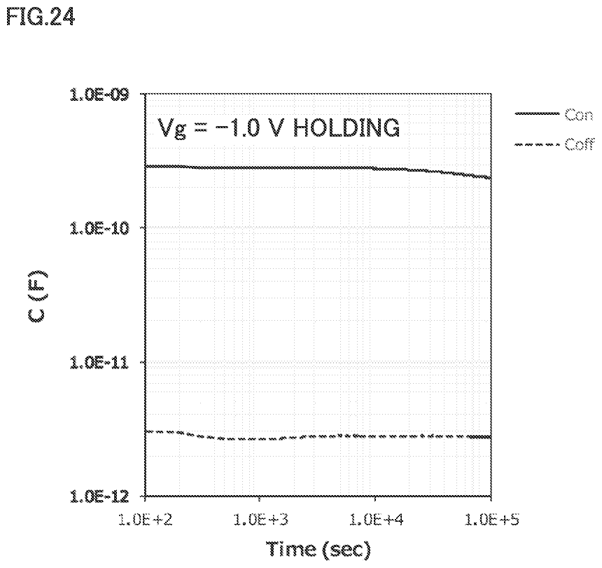

FIG. 24 is a diagram for explaining the relationship between the capacitance and the retention time of the variable capacitive element. In FIG. 24, the horizontal axis represents the time, and the vertical axis represents the capacitance. As illustrated in FIG. 24, capacitance value Cₒₙ and capacitance value C_{off} can be maintained without being changed for about 1.0×10⁵ sec (˜27 hours) while the holding voltage of −1.0 V is applied to gate electrode 2. Consequently, when the configuration of the ferroelectric gate transistor is adopted in variable capacitive elements 100 to 100g, the high gate voltage to hold the capacitance is not required to be applied, so that power saving can be achieved and degradation of the element can be prevented.

In general, it is noted that throughout this description, the embodiments and examples shown should be considered as exemplars, rather than limitations on the devices and methods disclosed or claimed. Although many of the examples presented herein involve specific combinations of method acts or elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

### REFERENCE SIGNS LIST

1: semiconductor substrate, la: silicon substrate, 2: gate electrode, 2a: control electrode terminal, 3: gate insulating film, 4: channel formation film, 5: source electrode, 5a, 22: terminal electrode, 6: drain electrode, 10: switch portion, 20: element portion, 21: dielectric, 22a: terminal, 23, 24: coil electrode, 25: nonmagnetic ceramic, 100, 100a to g: variable capacitive element, 200: variable inductance element, 300, 400, 500: circuit device

What is claimed:

1. A variable electronic element comprising:
a switch that configures a field effect transistor and that includes:
a source electrode;
a drain electrode;
a channel formation film that overlaps at least a part of the source electrode and a part of the drain electrode;
a gate insulating film that overlaps the channel formation film; and
a gate electrode that overlaps the gate insulating film; and
an element that is electrically connected to the switch to configure a passive element and that includes:
a first terminal electrode electrically connected to the source electrode; and
a second terminal electrode that configures a first passive element with the source electrode and that configures a second passive element at least with the drain electrode.

2. The variable electronic element according to claim 1, wherein the switch is on either an upper portion or a lower portion of the element.

3. The variable electronic element according to claim 1, wherein the passive element is at least one of a capacitor, an inductor, and a resistor.

4. The variable electronic element according to claim 1, wherein the passive element is a capacitor.

5. The variable electronic element according to claim 4, wherein:
the element further includes a dielectric that overlaps the source electrode and the drain electrode,
the dielectric is between the source electrode and the second terminal electrode to configure a first capacitor as the first passive element, and
the dielectric is between at least the drain electrode and the second terminal electrode to configure a second capacitor as the second passive element.

6. The variable electronic element according to claim 5, wherein:
the gate electrode is on a semiconductor substrate,
the gate insulating film is on the gate electrode and the semiconductor substrate,
the channel formation film is on the gate insulating film,
the source electrode and the drain electrode are on the channel formation film,
the dielectric is on the source electrode and the drain electrode, and
the second terminal electrode is on the dielectric.

7. The variable electronic element according to claim 1, wherein the passive element is an inductor.

8. The variable electronic element according to claim 7, wherein the element includes:
a first inductor that is electrically connected between the source electrode and the second terminal electrode and configured as the first passive element; and
a second inductor that is electrically connected between the drain electrode and the second terminal electrode and configured as the second passive element.

9. The variable electronic element according to claim 1, wherein a portion where the gate electrode overlaps the channel formation film in a planar view is configured as the drain electrode.

10. The variable electronic element according to claim 9, wherein the second passive element is configured between the second terminal electrode and the portion where the gate electrode overlaps the channel formation film.

11. The variable electronic element according to claim 1, wherein the second terminal electrode includes a first region that overlaps the source electrode in a planar view and a second region that overlaps the drain electrode in the planar view.

12. The variable electronic element according to claim 11, wherein the first region and the second region are electrically connected while bypassing at least a part of a channel region between the source electrode and the drain electrode.

13. The variable electronic element according to claim 5, wherein the second terminal electrode includes a first region that overlaps the source electrode in a planar view and a second region that overlaps the drain electrode in the planar view.

14. The variable electronic element according to claim 13, wherein:
the first region and the second region are electrically connected while bypassing at least a part of a channel region between the source electrode and the drain electrode, and
the dielectric avoids at least a part of the channel region between the source electrode and the drain electrode in accordance with a pattern of the second terminal electrode.

15. The variable electronic element according to claim 6, wherein the semiconductor substrate has an uneven portion.

16. A variable electronic element comprising:
a switch including:
a source electrode,
a drain electrode,
a channel formation film on at least a portion of the source electrode and a portion of the drain electrode,
a gate insulating film on the channel formation film, and
a gate electrode that overlaps the gate insulating film, and
a passive element that is electrically connected to the switch and includes:
a first terminal electrode electrically connected to the source electrode, and
a second terminal electrode that configures a first passive element with the source electrode and that configures a second passive element at least with the drain electrode.

17. The variable electronic element according to claim 16, wherein:
the passive element is a capacitor,
a dielectric is disposed on the source electrode and the drain electrode,
the dielectric is between the source electrode and the second terminal electrode to configure a first capacitor as the first passive element, and
the dielectric is between at least the drain electrode and the second terminal electrode to configure a second capacitor as the second passive element.

18. The variable electronic element according to claim 16, wherein the passive element is an inductor that includes:
a first inductor that is electrically connected between the source electrode and the second terminal electrode and configured as the first passive element, and
a second inductor that is electrically connected between the drain electrode and the second terminal electrode and configured as the second passive element.

19. A circuit device comprising:
a circuit wiring; and
the variable electronic element according to claim 1 electrically connected to the circuit wiring.

20. A circuit device comprising:
a circuit wiring; and
the variable electronic element according to claim 16 electrically connected to the circuit wiring.
